(19) United States
(12) Patent Application Publication
(10) Pub. No.: US 2005/0250291 A1
(43) Pub. Date: Nov. 10, 2005

(54) Methods for clearing alignment markers useable in semiconductor lithography

(76) Inventors: Pary Baluswamy, Boise, ID (US); Peter Benson, Boise, ID (US)

Correspondence Address: WONG, CABELLO, LUTSCH, RUTHERFORD & BRUCCULERI,;P.C., 20333 SH 249, SUITE 600, HOUSTON, TX, 77070, US

(21) Appl. No.: 10/840,324

(22) Filed: May 6, 2004

(51) Int. Cl. H01L 21/76

(52) U.S. Cl. 438/401

(57) ABSTRACT

Disclosed herein are methods for removing overlying materials on a substrate which otherwise might optically obscure an underlying photolithography alignment marker. According to the disclosed techniques, laser radiation is used to remove the material (e.g., a metal) in an area which overlies the alignment marker (e.g., formed in polysilicon). Such removal can comprise the use of laser ablation or laser-assisted etching. The substrate is placed on a motor-controlled chuck in a laser removal chamber, and the areas are automatically moved underneath the laser radiation to removal the material. Alternatively, a stencil having holes corresponding to the areas can be placed over the substrate to mitigate the need to move the substrate to the areas with precision. After clearance of the area, photoresist can then be applied to the material with the alignment marker now visible though the removed area, and the now-visible alignment marker can be used to pattern the photoresist to align the material with the alignment marker (and hence, other active structures formed of the same material as the alignment marker).

### CROSS REFERENCE TO RELATED APPLICATIONS

This application is related to U.S. patent application [attorney docket number 102-0114S], which is filed concurrently herewith, and which is incorporated by reference in its entirety.

### FIELD OF THE INVENTION

Embodiments of this invention relate to improved methods for aligning substrates during lithography.

### BACKGROUND

When fabricating an integrated circuit, and as is well known, a series of layers are deposited on a substrate (usually a crystalline silicon substrate) and are patterned and etched to form a circuit. For the circuit to work properly, it is important that each subsequent layer be aligned with the previously formed layer or layers, at least within some permissible tolerance.

To align the various layers, and referring to FIG. 1A, a substrate 12 having a photoresist applied thereon (not shown) is placed in a photolithographic chamber 10, sometimes referred to as a “stepper” or “scanner.” In the stepper 10, a mask or reticle 27 is used to pattern the photoresist. As the patterned photoresist ultimately dictates the positioning of the underlying circuit layer to be etched, its alignment is critical.

To bring the substrate 12 into alignment with the mask, an image of some structure on the mask and some structure 24 on the wafer are compared using well-known optical analysis equipment 14, with such images being received by optical sensors 20. If alignment is needed, the optical analysis equipment 14 can control the positioning of a chuck 16 on which the substrate 12 sits via motor stages 18, which, for example, can move the chuck 16 along the X-axis, Y-axis, or rotational θ-axis as appropriate. Such alignment is usually assessed at numerous locations around the substrate 12's perimeter, which accordingly requires reference to a plurality of alignment structures 24 on the substrate 12, as shown in FIG. 1B. However, reference to a single alignment marker could also be used.

Although alignment structures 24 can constitute an actual active portion of the circuit being fabricated, a dedicated inactive structure is usually formed for this purpose—what is referred to as an alignment marker. Referring to FIG. I B, such alignment markers 24 are typically formed outside of the active integrated circuit area 22 on the wafer, i.e., in the area in which the substrate will be scribed or “diced” for later insertion into packages. A simple “cross” pattern is illustrated for the alignment marker 24, but as one skilled in the art will understand, such markers can come in a variety of different shapes and sizes (e.g., chevrons, gratings, squares, etc.), depending on the alignment task be performed. Typically, more than one alignment marker 24 is fabricated on the substrate 12 as shown, which may range from approximately 20 to 500 microns in size.

Traditional alignment markers 24 suffer from drawbacks which hamper their utility. For example, sometimes it is desirable when patterning a circuit layer to make reference to an alignment marker that was previously patterned in an underlying circuit layer so that the two layers can be brought into alignment. To show a specific example, suppose it is desired to align a metal layer 30 (e.g., of aluminum) for patterning with a previously patterned alignment marker 24 formed in an underlying polysilicon (poly) layer 32, as shown in FIG. 2. Such alignment is beneficial, for example, to ensure that active structures formed in the metal layer 30 are well-aligned with any contacts that might go to the poly layer 32. As shown in FIG. 2B, a dielectric layer (or layers) 31 such as a silicon dioxide intervenes between the metal 30 and poly 32, which is generally transparent. However, the just-deposited metal 30 is not transparent, and as a result the poly-based alignment marker is not visible to the optical sensors 20 (FIG. 1A).

Accordingly, to align and ultimately pattern the metal 30, the prior art teaches to initially perform a photolithography patterning and etch step to remove the metal 30 where it overlies the alignment marker 32, 24. This is shown initially in FIGS. 2A and 2B, which shows the previously formed poly-based alignment marker 32, 24, a transparent dielectric 31 (e.g., silicon dioxide), the metal layer 30 to be patterned and aligned to the poly-based alignment marker 32, 34, and an overlying photoresist 35. The photoresist 35 is exposed (not shown) using a special mask (not shown) having opening only overlying the alignment markers 32, 24 and otherwise not useful in the formation of active structures. The exposed photoresist is then removed to expose the underlying metal layer 30 as shown in FIGS. 2C and 2D. Alignment of the mask to expose the photoresist 35 is not terribly critical as the alignment markers 32, 24 are relatively large and generally have ample space around their peripheries; thus they are easily exposed without the need for sensitive alignment procedures.

The metal layer 30 is then removed by wet or dry (e.g., plasma) etching (FIGS. 2E and 2F), and another photoresist layer 37—that which will be used to actually pattern the metal layer into useful active structures—is formed over the resulting surface (FIGS. 2G and 2H). Because the dielectric 31 and photoresist layers 37 are generally transparent, the underlying alignment marker 32, 24 can now be “seen” by the optical sensor 20, analyzed by the optical analysis equipment 14, and aligned into position with the metal mask (not shown) by motor stages 18. (Alternatively, the photoresist 37 can again be exposed and removed over the alignment marker prior to this alignment step). Once aligned, the photoresist 37 is then exposed (not shown) via the aligned metal mask, and the metal layer 30 is etched to form useful active structures, such as line 24 (FIG. 21), in good alignment with structures earlier formed in the polysilicon layer 32.

However, this alignment scheme is not ideal. First, this scheme requires two photolithography pattern and etch steps of the metal 30: a first (relatively crudely aligned) step to clear the metal 30 over the poly-based alignment marker 32, 24, followed by a second step using the now-exposed poly-based alignment marker 32 to pattern and etch true active structures in the metal layer 30 with precision. Thus, an additional photolithography and etch step (FIGS. 2A-2F) is required, as is an additional mask. Second, such additional processing creates a contamination risk. For example, the photoresist 35 may not be completely removed, which may cause 37 scumming.”

In short, present methods to clear the overlying materials from underlying photolithography alignment markers are too complex, too costly, and present a contamination risk. Accordingly, the art would be benefited by improved methods for clearing alignment markers. This disclosure provides solutions.

### SUMMARY

Disclosed herein are methods for removing overlying materials on a substrate which otherwise might optically obscure an underlying photolithography alignment marker. According to the disclosed techniques, laser radiation is used to remove the material (e.g., a metal) in an area which overlies the alignment marker (e.g., formed in polysilicon). Such removal can comprise the use of laser ablation or laser-assisted etching. The substrate is placed on a motor-controlled chuck in a laser removal chamber, and the areas are automatically moved underneath the laser radiation to removal the material. Alternatively, a stencil having holes corresponding to the areas can be placed over the substrate to mitigate the need to move the substrate to the areas with precision. After clearance of the area, photoresist can then be applied to the material with the alignment marker now visible though the removed area, and the now-visible alignment marker can be used to pattern the photoresist to align the material with the alignment marker (and hence, other active structures formed of the same material as the alignment marker). Accordingly, a separate photolithography step to clear the area of material overlying the alignment markers is not necessary, saving time and cost, and reducing potential sources of contamination.

### BRIEF DESCRIPTION OF THE DRAWINGS

Embodiments of the inventive aspects of this disclosure will be best understood with reference to the following detailed description, when read in conjunction with the accompanying drawings, in which:

FIG. 1A illustrates a prior art photolithographic stepper for optically sensing alignment markers on a substrate, and FIG. 1B illustrates a top-down view of the alignment markers on the substrate.

FIGS. 2A-2I illustrates using cross-sectional views a prior art technique for clearing an opaque material overlying the alignment markers requiring a photolithography step.

FIG. 3 illustrates a prior art laser ablation or laser-assisted etch chamber useful in accordance with the disclosed technique for removing the opaque material overlying the alignment markers without the need for a photolithography step.

FIGS. 4A-4F illustrate using cross-sectional views the disclosed technique for removing the opaque material overlying the alignment markers using laser radiation and without the need for a photolithography step.

FIG. 5 illustrates a modification in which a stencil is use to mask the laser radiation to assist in the accurate removal of the opaque material.

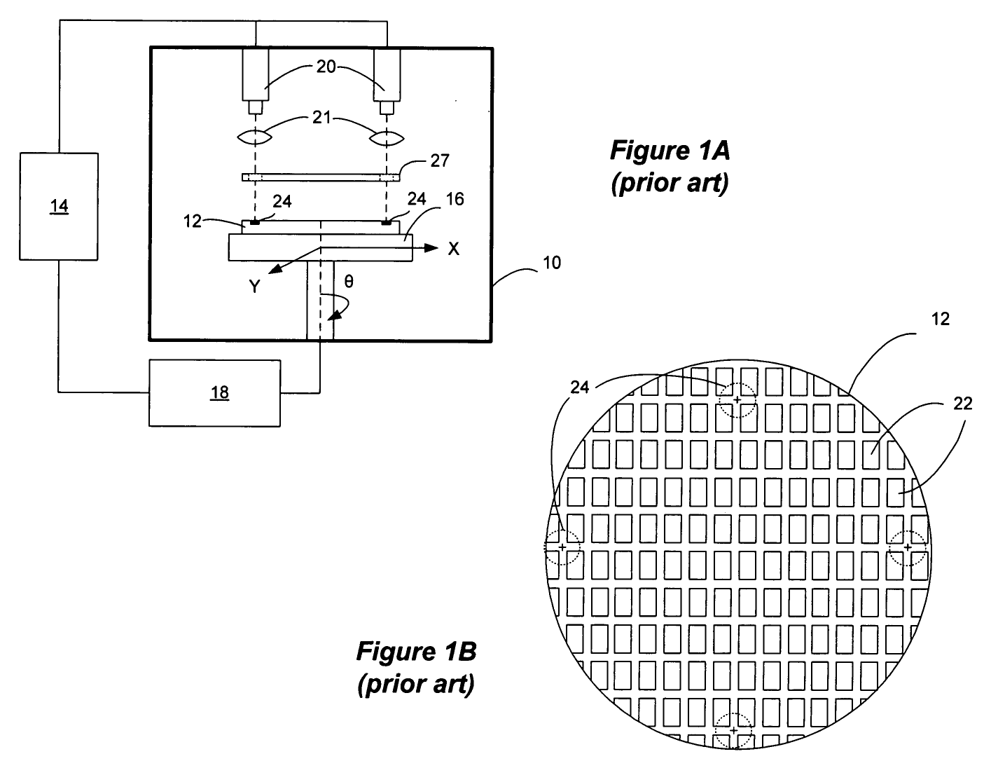

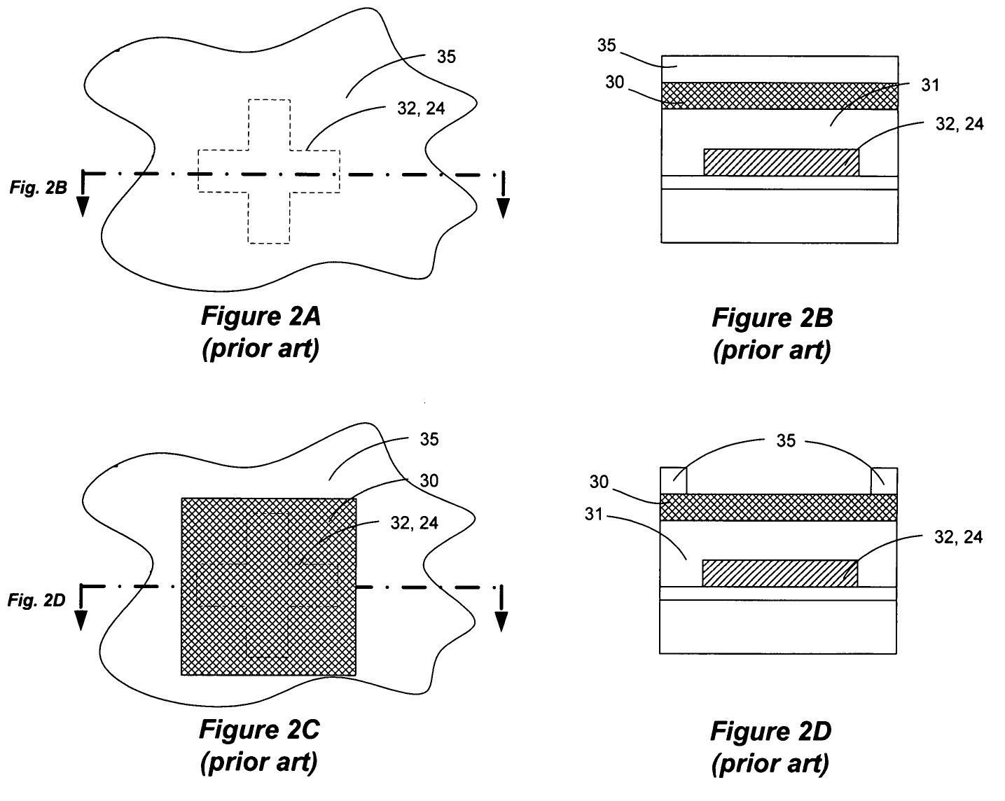

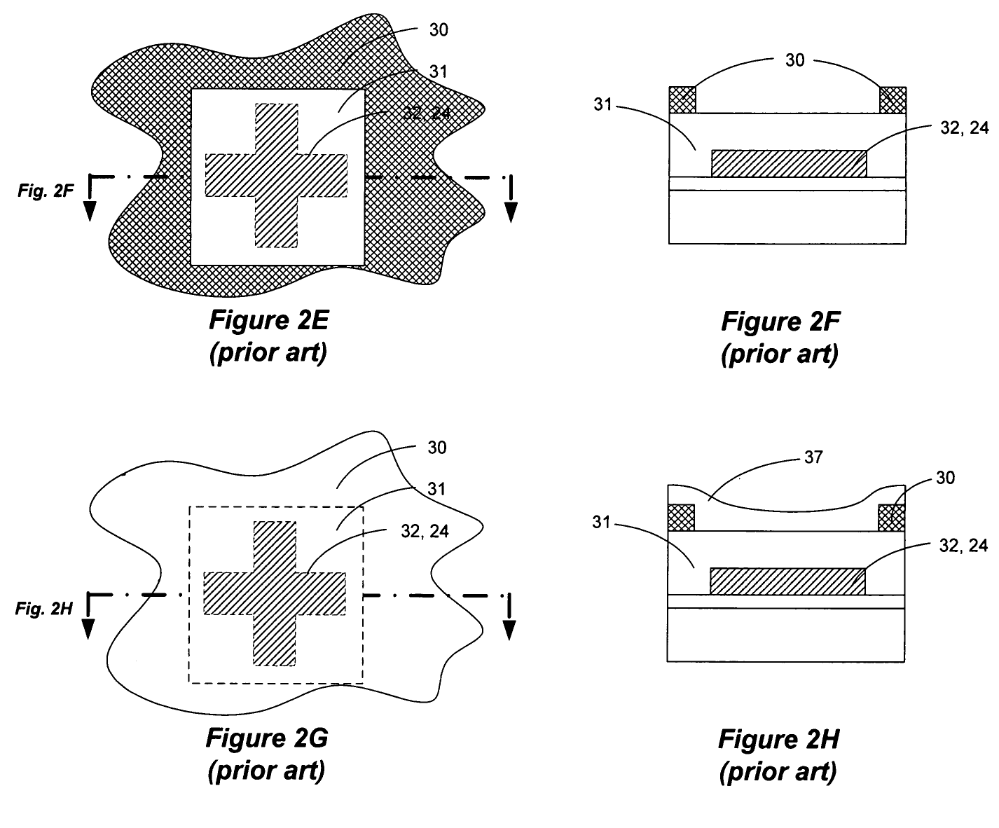

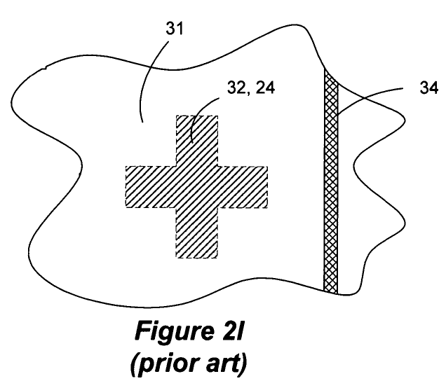

### DETAILED DESCRIPTION

In one embodiment of the disclosed invention, laser-assisted etching or laser ablation is used to remove overlying materials which otherwise might optically obscure an underlying alignment marker. In this regard, it should be noted that both laser-assisted etching and laser ablation are well-known techniques that have been used to etch or remove materials on integrated circuits. Accordingly, only basic aspects of these techniques are discussed, with the focus of the discussion centering on aspects relevant to the alignment marker issues discussed earlier.

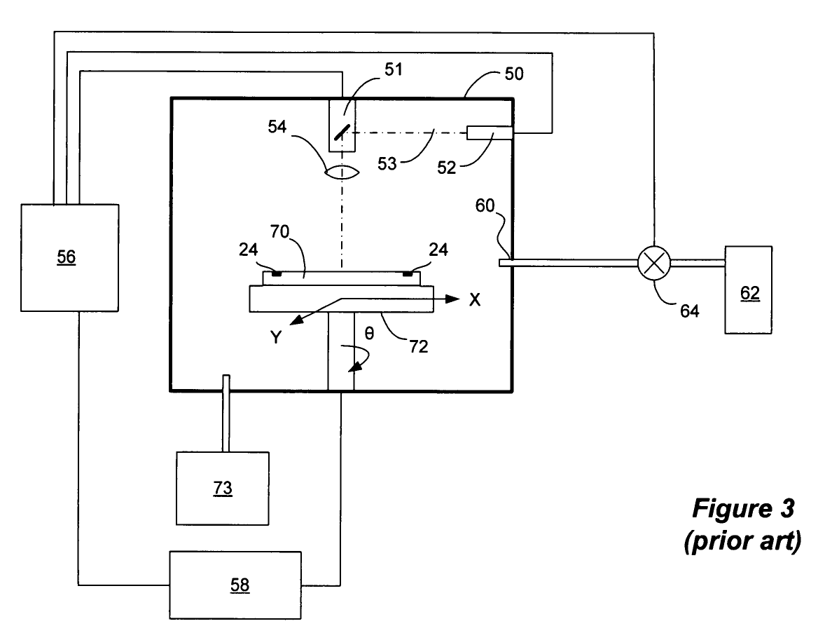

In FIG. 3, a laser-assisted etch/laser ablation chamber 50 is shown, and which is used in this embodiment to remove the overlying metal (or other opaque material) present on the wafer and overlying the alignment marker or markers 24 of interest. The chamber includes an optical sensor 51, a laser 52, a lens or lenses 54, a computer 56, motor stages 58, a gas inlet port 60 coupled to an etchant gas source 62 via a valve 64, and a purge pump 73. Placed within the chamber 50 is a substrate 70 to be etched or ablated on a moveable chuck 72. Such chambers are well known, and will vary in design depending on whether laser-assisted etching or laser ablation techniques are used. Because a gas inlet port 60, an etchant gas source 62, and a purge pump 73 are shown, chamber 50 as illustrated more accurately represents a laser assisted-etching chamber. Were laser ablation to be used for the application in question, such gas- and etching-specific structures may not be necessary.

The laser 52 is used to etch or ablate the material (e.g., metal) overlying the alignment markers without the need to practice the photolithography steps of the prior art (photoresist deposition, exposure, cleaning and removal of the photoresist, etc.), and without the need to fabricate a special mask exclusively for that purpose. In this regard, the substrate 70 is initially aligned in the chamber 50. This alignment can be relatively crude, and need not be as sophisticated as the alignment schemes used to align the various circuit layers in the device because, as mentioned earlier, the alignment markers 32, 24 are relatively large and generally have ample area surrounding them. Thus, initial alignment need only be ±5 microns for example, and can be performed manually, via operator visual inspection through a microscope, or by automated optical detection schemes, such as automated detection of the edges of the substrate 70 via the use of the optical sensor 51.

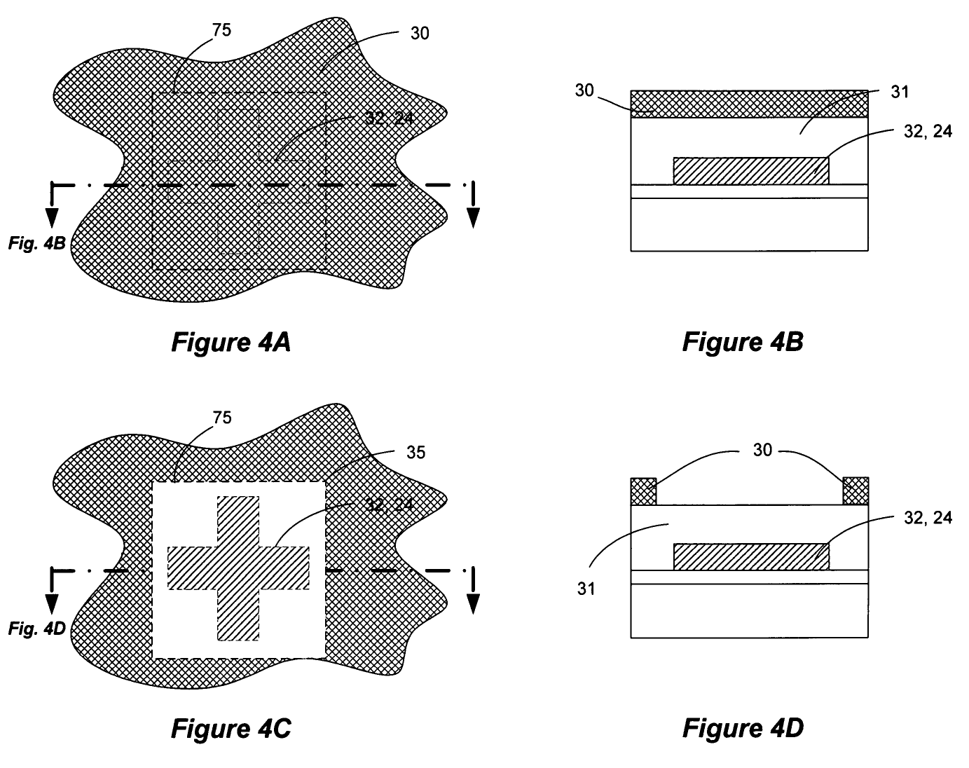

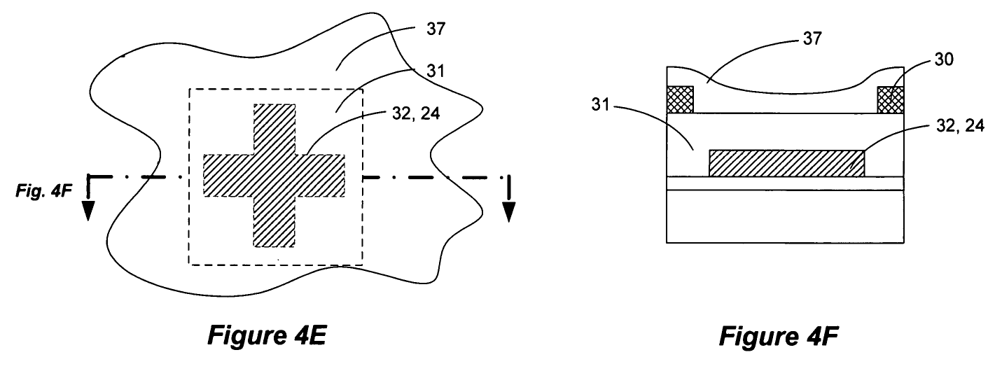

Once aligned, computer 56 executes a program specific for the substrate 70 in question, and armed with knowledge of the X, Y coordinates of the location of the areas 75 (FIG. 4A) on the substrate 70 to be cleared over the alignment markers 32, 24. Accordingly, the computer 56, moving the chuck 72 via motor stages 58, brings the areas 75 into alignment and engages the laser 52 to form laser radiation 53 to etch or ablate the material, e.g., metal layer 30 (FIGS. 4A-4D). Thereafter, the surface can be cleaned if necessary. The resulting structure is then coated with photoresist 37 (FIGS. 4E-4F) for the purpose of patterning and etching metal layer 30 to form useful active structures. Because the metal layer 30 has been removed and the alignment markers 32, 24 are now visible, and the photoresist 37 can be patterned with good alignment.

In short, the areas 75 over the alignment markers 32 are cleared without the need to apply an additional photoresist, and without the need for a clearing mask. As noted, this saves time, cost, and reduces potential contamination.

It should be noted that techniques for using laser-assisted etching and laser ablation of materials on semiconductor substrates are well known, and hence are not reiterated in much detail herein. Considerations relevant to such selective area processing can be found in Thin Film Processes II, (ed. John L. Vossen & Werner Kern), pp. 621-670, 749-856 (Academic Press 1991), which is submitted herewith and which is incorporated herein by reference.

Laser ablation is preferably accomplished using an excimer, YAG, or ND-YAG laser which essentially vaporizes the metal layer 30 or other material where it is focused. Suitable ND-YAG lasers have wavelengths of 355 nm, and suitable excimer lasers have wavelengths of 193 nm or 248 nm. Power levels for such lasers are typically in the 1-Watt range. Laser ablation is simpler to implement, and will remove material relatively quickly, but is more difficult to control. Moreover, the vaporized material may need to be cleaned from the substrate 70's surface. This being said however, laser ablation can be a suitable choice for clearing the material above an alignment marker in some applications. Exemplary excimer lasers include the PL-1500A Excimer Laser manufactured by Potomac Photonics, Inc., and the xsie200 Excimer Laser manufactured by Xsil Ltd.. An exemplary YAG laser suitable for ablation comprises that LAM 66 manufactured by Heidelberg Instruments Mikrotechnik GmbH. Further details regarding considerations for laser ablation can be found at http://www.me.mtu.edu/˜microweb/chap4/ch4-2.htm, http://www.me.mtu.edu/˜microweb/graph/laser/fluence.jpg, and http://www.me.mtu.edu/˜microweb/graph/laser/specmet.jpg, which are submitted herewith and which are incorporated by reference in their entireties.

Laser-assisted etching, by contrast, is slower, but better controlled, and hence is preferred for the application in question. In laser-assisted etching, an etchant gas is introduced into the chamber 50 from an etchant gas source 62 through valve 64 and gas inlet port 60. The etchant gas is preferably introduced into the chamber 50 as shown proximate to and parallel with the substrate 70's surface. Interaction of the laser light and the etchant gas produces a controlled reaction at the surface of the substrate to remove the material in question. Of course, the etchant gas to be used for a particular application, as well as the laser 52 parameters (wavelength; power; spot size) will depend on the material to be removed, but again such laser-assisted processes are well known. Assuming that the metal layer to be removed in the present application is aluminum based, a chlorine-based etchant gas would be used. If silicon or polysilicon is being etched, SF₆ would be a suitable etchant gas and would be used in conjunction with a laser having approximately 10 um wavelength. An exemplary laser-assist etch chamber 50 can comprise the laser etch and deposition chamber published at http://www.mesofab.com, which is submitted herewith and which is incorporated herein by reference.

Because the area 75 in which material will be removed will generally be relatively large compared to the spot size of the laser radiation 53, removal will preferably be accomplished by rastering the area 75 underneath the laser radiation. The laser 52 can either run continuously, or can be turned on and off at each rastered location. Alternatively, if the laser spot size is large enough and comparable with the size of area 75, rastering may not be necessary.

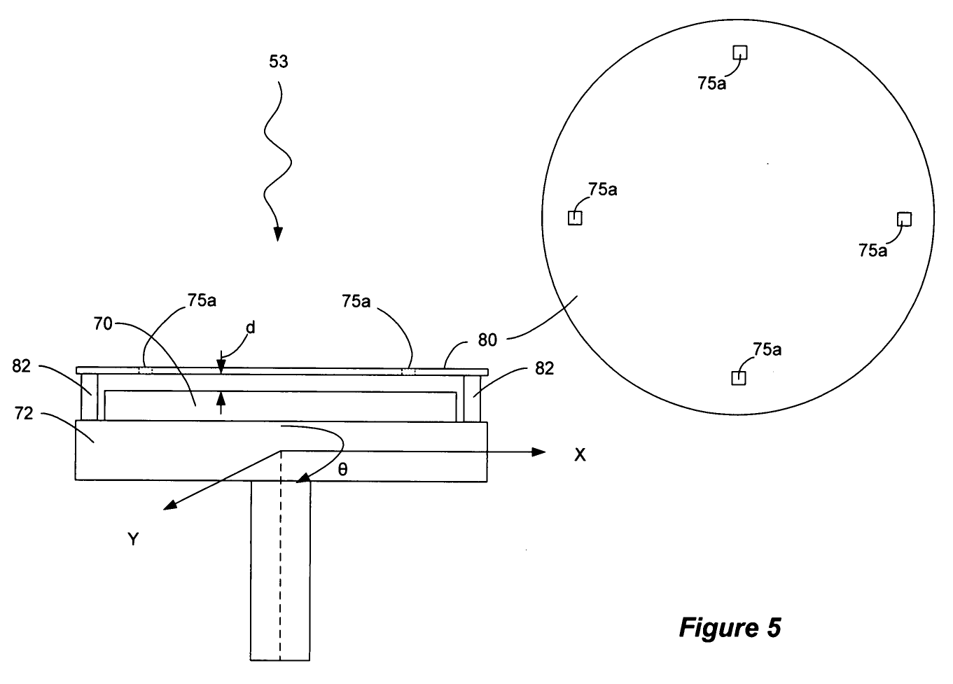

In an alternative embodiment, the need for the computer 56 to know the X, Y coordinates of the areas 75 to be removed is mitigated by the use of a stencil 80, as shown in FIG. 5. According to this alternative, the stencil 80 is roughly aligned with the substrate 70, and contains holes 75a which correspond to the areas 75 on the wafer to be cleared. The stencil 80 is raised a distance ‘d’ away from the surface of the substrate 70 by spacers 82, which distance might range from approximately 2 to 10 microns. Using this approach, the laser 52 can be rastered over the entire surface of the stencil 80, yet will only have effect to remove the material of interest above the alignment markers where such material is exposed through the holes 75a. Accordingly, once the stencil 80 is appropriately aligned with the substrate 75, using any of the techniques mentioned earlier, radiation from the laser 52 can be rastered across the entirety of the substrate 70's surface, although it is still generally preferable to move the substrate 70 and stencil 80 to at least the general X-Y coordinates of the holes 75a so that laser radiation 53 is not needlessly spent on solid portions of the stencil 80.

Using this approach, the computer 56 need only understand the area of the substrate, instead of the exact X-Y coordinates of each of the areas 75 that might need clearing. Moreover, the stencil 80 ensures good alignment of the radiation with the desired areas 75, making laser alignment and spot size considerations less critical. (Indeed, the use of a laser in conjunction with a stencil overlying the wafer has utility to clearing materials over and above just those covering the alignment markers, and can be used for patterning active circuits as well). Because the areas 75 to be cleared are relatively large, diffractive effects occurring at the edges of the holes 75a of the stencil 80 should not be problematic, although optical proximity corrective measures could be incorporated into the stencil 80 if necessary. If used in a laser-assisted etch application, a material should be chosen for the stencil that will not react to the etchant gases in question. For example, for a chlorine-based etch, silicon would be a good choice as the material for the stencil. Likewise, in a laser ablation application, a material should be chosen which will remain impervious to the laser radiation 53 in question.

Although the removal of a metal layer over alignment markers has been described in detail, it should be understood that the disclosed technique for clearing materials over alignment markers is not limited to the removal of metals. One skilled in the art will appreciate that many different types of opaque materials may require removal over alignment markers, and that the techniques disclosed herein can be used to remove such materials by adjusting the etchant gases used, the laser parameters, etc. Again, laser ablation and laser-assisted etching processes are known for the removal of many different types of materials on substrates.

Moreover, while particularly useful to the clearing of materials on semiconductor integrated circuit substrates, the disclosed techniques can have application to other types of substrates and other types of processes requiring optical alignment.

Additionally, it should be realized that in the fabrication of an integrated circuit that it may be necessary to perform the laser-assisted clearing steps several times during the integrated circuit's manufacture. For example, modern-day integrated circuits typically employ several layers of polysilicon, metals, or other types of opaque materials, and hence these materials may each need to be cleared above the alignment markers in question at various steps during the integrated circuit's manufacture.

While it is preferred to use radiation, and specifically laser radiation, to remove the material overlying the alignment markers, this is not strictly necessary. One skilled in the art will realize that other techniques for selectively removing discrete areas of materials without the use of a photoresist exist in the art, and these could be used as well. For example, an electron or other particle beam (e.g., an ion beam) could be used in much the same way as the disclosed laser radiation is used to remove the material (e.g., the metal layer) by the use of a rastered beam to directly remove the material without the need for photoresist or photolithography. The use of such alternative beams can also be accompanied by the use of a stencil as disclosed herein. Again, processes for using electron or particle beams to remove materials from semiconductor integrated circuits are well known, and can be found in the Thin Film Processes book incorporated above.

Furthermore, while particularly useful in the removal of overlying opaque layers, the disclosed techniques can be used to remove semi-opaque or even completely translucent materials overlying the alignment markers, as removal of such layers may improve the overall optical image of the alignment markers “seen” by the optical sensor, and hence can improve the accuracy of use of the alignment markers.

It should be understood that the inventive concepts disclosed herein are capable of many modifications. To the extent such modifications fall within the scope of the appended claims and their equivalents, they are intended to be covered by this patent.

1. A method for processing and using an alignment marker on a substrate, comprising:
forming at least one alignment marker on the substrate;
forming a material on the substrate and overlying the at least one alignment marker;
removing the material overlying the at least one alignment marker using radiation;
forming a photoresist over the structure resulting from the proceeding steps; and
assessing the position of at least one alignment marker to pattern the photoresist in alignment with the alignment marker.

2. The method of claim 1, wherein the radiation comprises radiation from a laser.

3. The method of claim 2, wherein the laser radiation removes the material by ablation.

4. The method of claim 2, wherein removing the material further comprises exposing the material to an etchant gas, and wherein the laser radiation interacts with the etchant gas to remove the material.

5. The method of claim 1, wherein assessing the position of the alignment marker comprises an optical assessment.

6. The method of claim 1, further comprising removing the patterned photoresist and etching the material using non-patterned photoresist as a mask.

7. The method of claim 1, wherein patterning the photoresist comprises aligning the assessed position of the alignment marker with a mask.

8. The method of claim 1, wherein the alignment marker is formed in a layer on the substrate.

9. The method of claim 1, wherein the material is opaque.

10. The method of claim 1, wherein removing the material comprises masking the radiation with a stencil offset from the substrate by a distance.

11. The method of claim 1, wherein removing the material overlying the at least one alignment marker comprises removing only the material overlying the at least one alignment marker.

12. A method for processing and using an alignment marker on a substrate, comprising:
forming at least one alignment marker on the substrate;
forming a material on the substrate and overlying the at least one alignment marker;
removing the material overlying the at least one alignment marker without using a photoresist;
forming a photoresist over the structure resulting from the proceeding steps; and
assessing the position of at least one alignment marker to pattern the photoresist in alignment with the alignment marker.

13. The method of claim 12, wherein the removing the material comprises the use of laser radiation.

14. The method of claim 13, wherein the laser radiation removes the material by ablation.

15. The method of claim 13, wherein removing the material further comprises exposing the material to an etchant gas, and wherein the laser radiation interacts with the etchant gas to remove the material.

16. The method of claim 12, wherein assessing the position of the alignment marker comprises an optical assessment.

17. The method of claim 12, further comprising removing the patterned photoresist and etching the material using non-patterned photoresist as a mask.

18. The method of claim 12, wherein patterning the photoresist comprises aligning the assessed position of the alignment marker with a mask.

19. The method of claim 12, wherein the alignment marker is formed in a layer on the substrate.

20. The method of claim 12, wherein the material is opaque.

21. The method of claim 12, wherein removing the material comprises use of a stencil offset from the substrate by a distance.

22. The method of claim 12, wherein removing the material overlying the at least one alignment marker comprises removing only the material overlying the at least one alignment marker.

23. A method for processing and using an alignment marker on a substrate, comprising:
forming at least one alignment marker on the substrate;
forming a material on the substrate and overlying the at least one alignment marker;
removing the material overlying the at least one alignment marker using radiation; and
using the at least one alignment marker to align the substrate.

24. The method of claim 23, wherein the radiation comprises radiation from a laser.

25. The method of claim 24, wherein the laser radiation removes the material by ablation.

26. The method of claim 24, wherein removing the material further comprises exposing the material to an etchant gas, and wherein the laser radiation interacts with the etchant gas to remove the material.

27. The method of claim 23, wherein the alignment marker is formed in a layer on the substrate.

28. The method of claim 23, wherein the material is opaque.

29. The method of claim 23, wherein removing the material comprises masking the radiation with a stencil offset from the substrate by a distance.

30. The method of claim 23, wherein removing the material overlying the at least one alignment marker comprises removing only the material overlying the at least one alignment marker.

31. A method for processing and using an alignment marker on a substrate, comprising:
forming at least one alignment marker on the substrate;
forming a material on the substrate and overlying the at least one alignment marker;
removing the material overlying the at least one alignment marker without using a photoresist; and
using the at least one alignment marker to align the substrate.

32. The method of claim 31, wherein the removing the material comprises the use of laser radiation.

33. The method of claim 32, wherein the laser radiation removes the material by ablation.

34. The method of claim 32, wherein removing the material further comprises exposing the material to an etchant gas, and wherein the laser radiation interacts with the etchant gas to remove the material.

35. The method of claim 31, wherein the alignment marker is formed in a layer on the substrate.

36. The method of claim 31, wherein the material is opaque.

37. The method of claim 31, wherein removing the material comprises use of a stencil offset from the substrate by a distance.

38. The method of claim 31, wherein removing the material overlying the at least one alignment marker comprises removing only the material overlying the at least one alignment marker.

39. A method for processing and using an alignment marker on a substrate, comprising:
forming at least one alignment marker on the substrate;
forming a material on the substrate and overlying the at least one alignment marker;
removing the material overlying the at least one alignment marker using radiation;
forming a photoresist over the structure resulting from the proceeding steps;
using the at least one alignment marker to align the substrate with a mask;
patterning the photoresist using the mask;
removing the patterned photoresist to expose portions of the material; and
etching the exposed portions of the material.

40. The method of claim 39, wherein the radiation comprises radiation from a laser.

41. The method of claim 40, wherein the laser radiation removes the material by ablation.

42. The method of claim 40, wherein removing the material further comprises exposing the material to an etchant gas, and wherein the laser radiation interacts with the etchant gas to remove the material.

43. The method of claim 39, wherein the alignment marker is formed in a layer on the substrate.

44. The method of claim 39, wherein the material is opaque.

45. The method of claim 39, wherein removing the material comprises masking the radiation with a stencil offset from the substrate by a distance.

46. The method of claim 39, wherein removing the material overlying the at least one alignment marker comprises removing only the material overlying the at least one alignment marker.

47. A method for processing and using an alignment marker on a substrate, comprising:
forming at least one alignment marker on the substrate;
forming a material on the substrate and overlying the at least one alignment marker;
removing the material overlying the at least one alignment marker without using a photoresist;
forming a photoresist over the structure resulting from the proceeding steps;
using the at least one alignment marker to align the substrate with a mask;
patterning the photoresist using the mask;
removing the patterned photoresist to expose portions of the material; and
etching the exposed portions of the material.

48. The method of claim 47, wherein the removing the material comprises the use of laser radiation.

49. The method of claim 48, wherein the laser radiation removes the material by ablation.

50. The method of claim 48, wherein removing the material further comprises exposing the material to an etchant gas, and wherein the laser radiation interacts with the etchant gas to remove the material.

51. The method of claim 47, wherein the alignment marker is formed in a layer on the substrate.

52. The method of claim 47, wherein the material is opaque.

53. The method of claim 47, wherein removing the material comprises use of a stencil offset from the substrate by a distance.

54. The method of claim 47, wherein removing the material overlying the at least one alignment marker comprises removing only the material overlying the at least one alignment marker.
